(19) United States
(12) Patent Application Publication
(10) Pub. No.: US 2013/0158922 A1
(43) Pub. Date: Jun. 20, 2013

(54) ESTIMATION OF A QUANTITY RELATED TO IMPEDANCE

(71) Applicants: Antoni Fertner, Stockhom (SE); Henrik Almeida, Hagersten (SE); Miguel Berg, Upplands Vasby (SE); Per Ola Börjesson, Lund (SE); Klas Ericson, Alvsjo (SE); Fredrik Lindqvist, Jarfalla (SE)

(72) Inventors: Antoni Fertner, Stockhom (SE); Henrik Almeida, Hagersten (SE); Miguel Berg, Upplands Vasby (SE); Per Ola Börjesson, Lund (SE); Klas Ericson, Alvsjo (SE); Fredrik Lindqvist, Jarfalla (SE)

(73) Assignee: TELEFONAKTIEBOLAGET L M ERICSSON (PUBL), Stockholm (SE)

(21) Appl. No.: 13/331,200

(22) Filed: Dec. 20, 2011

(51) Int. Cl. G06F 19/00; G01R 27/02

(52) U.S. Cl. 702/70; 702/57

(57) ABSTRACT

Method, arrangement and network node/device for estimating a quantity related to impedance in a first frequency interval, D1, of a telecommunication transmission line where the transmission line has a length d. The method involves determining a quantity related to impedance of the telecommunication transmission line for at least two frequencies, f1_{D2} and f2_{D2}, in a second frequency interval D2. The frequencies f1_{D2} and f2_{D2} should fulfil the condition that the line length d times the absolute value of the difference between a line propagation constant γ(f1)_{D2} and a line propagation constant, γ(f2)_{D2}, is less than π, i.e. abs(d*γ(f1)_{D2}−d*γ(f2)_{D2})<π. The method further involves estimating a quantity related to impedance in the first frequency interval D1 based on the determined quantity related to impedance in the second frequency interval D2, where the estimating involves the fitting of a Puiseux series to the determined quantity related to impedance in frequency interval D2.

### TECHNICAL FIELD

The invention relates in general to analysis of impedance in a transmission line, and in particular to the enabling of the same by estimation of a quantity related to impedance in a frequency interval.

### BACKGROUND

In telephone networks the copper line arrangement between CO (Central Office) and CP (Customer Premises) is often not known. A method to identify the make-up of the network is SELT (Single Ended Line Testing). SELT is based on the assumption that each discontinuity within a network results in a unique response which allows identification of the discontinuity in question. This response can be analyzed in time (Time Domain Reflectometry, TDR) or frequency domain (Frequency Domain Reflectometry, FDR) or both. The input impedance, or one-port scattering parameter, S₁₁, echo may be considered as a response of a physical network to an electrical stimulus.

Single-Ended Line Test (SELT [ITU-T G.996.2]) may be used e.g. for FDR for xDSL, i.e. ADSL (Asymmetric Digital Subscriber Line, VDSL2 (Very-high-speed Digital Subscriber Line 2), etc. In SELT, a wideband signal is used to measure an Uncalibrated Echo frequency Response (UER). After calibration, it is possible to get an estimate of the input impedance Zᵢₙ of the transmission line or any other Device Under Test (DUT). Further, the input impedance can be converted to some other representation, e.g. a complex, frequency-dependent input reflection coefficient ρᵢₙ based on the system impedance Z₀ (sometimes also known as reference impedance) and the input impedance of the DUT:

$${ρ}_{in} = \frac{{Z}_{in} - {Z}_{0}}{{Z}_{in} + {Z}_{0}}$$

If the DUT including termination is treated as a 1-port, the complex input reflection coefficient is equal to the input scattering parameter S₁₁, which is well known e.g. in microwave theory.

In an FDR system, it may be desired to emulate TDR (for more information on TDR, see or “google” e.g. Agilent AN1304-2) e.g. by taking the Inverse Fast Fourier Transform (IFFT) of a windowed (filtered) frequency domain parameter (e.g. UER, Zᵢₙ, or ρᵢₙ). Often, it is preferred to use the input reflection coefficient since the input impedance goes to infinity at low frequencies for certain configurations, which will give problems with the transform. If the frequency-domain parameter is valid down to zero frequency (DC), the resulting time-domain parameter (e.g. impulse response) can be used in a similar way as a true TDR, e.g. to determine the phase of the reflection coefficient for each time-domain echo of interest. A positive reflection means that impedance increases while a negative reflection means that impedance decreases. Further, such an impulse response can be integrated over time to give an equivalent step response. A step response is advantageous since it can be converted to show the impedance profile versus time. In certain cases, this can be translated to impedance versus distance. A further advantage of having a frequency domain parameter valid down to DC is that the IFFT window needed to reduce time domain ringing can have low-pass characteristic instead of band-pass characteristic, which could potentially improve time-domain resolution by a factor of two.

Many FDR systems have band-pass characteristics and thus cannot measure down to DC. This is natural when performing measurements on devices with band-pass characteristic but also means that the above advantages do not apply. In order to perform low-pass equivalent TDR processing, some prior art [U.S. Pat. No. 4,995,006A1] uses down-conversion and phase unwinding while other [Dodds2006] uses simple zero-filling of the input reflection.

[U.S. Pat. No. 4,995,006A1] solves the problem of low-pass equivalent processing mainly by performing an IFFT of a band-pass signal and down-converting the result to baseband (low-pass). After phase unwinding for a given echo of interest, this gives the sign of the reflection, showing negative for low impedance and positive for high impedance.

[Dodds2006] uses zero filling together with an IFFT starting at zero frequency. This is mathematically equivalent to a band-pass IFFT followed by down-conversion. A problem with all such solutions is that time domain ringing may become excessive since it corresponds to windowing with a rectangular window, creating a sinc (sin(x)/x) response in time domain.

### SUMMARY

A basic principle of the invention may be described as to use determined/measured values of an input parameter (input impedance or other parameter related to input impedance) in a sufficiently narrow frequency interval and extrapolate this parameter to lower (e.g. down to DC) and/or higher frequencies. This extrapolation can then be used for e.g. low-pass TDR processing. The extrapolation is enabled by the fitting of a series to a determined input parameter. The fitted series, or a function determined from the fitted series, is then used in the extrapolation.

According to a first aspect, a method is provided for estimating a quantity related to impedance in a first frequency interval, D1, of a telecommunication transmission line. The transmission line has a length d. The method involves determining a quantity related to impedance of the telecommunication transmission line for at least two frequencies, f1_{D2} and f2_{D2}, in a second frequency interval D2. The frequencies f1_{D2} and f2_{D2} should then fulfill the condition that the line length d times the absolute value of the difference between a line propagation constant γ(f1)_{D2} and a line propagation constant, γ(f2)_{D2}, is less than π, i.e. abs(d*γ(f1)_{D2}−d*γ(f2)_{D2})<π. The method further involves estimating a quantity related to impedance in the first frequency interval D1 based on the determined quantity related to impedance in the second frequency interval D2, where the estimating involves the fitting of a Puiseux series to the determined quantity related to impedance in frequency interval D2.

According to second aspect, an arrangement is provided for estimating a quantity related to impedance in a first frequency interval, D1, of a telecommunication transmission line having a length d. The arrangement comprises processing circuitry, e.g. arranged as a determining unit, an estimation unit and a further processing unit, configured to determine a quantity related to impedance of the telecommunication transmission line for at least two frequencies, f1_{D2} and f2_{D2}, in a second frequency interval D2, for which frequencies the line length d times the absolute value of the difference between a line propagation constant γ(f1)_{D2} and a line propagation constant, γ(f2)_{D2}, is less than π, i.e. abs(d*γ(f1)_{D2}−d*γ(f2)_{D2})<π; and. The processing circuitry is further configured to estimate a quantity related to impedance in the first frequency interval D1 based on the determined quantity related to impedance in the second frequency interval D2. The estimating involves the fitting of a Puiseux series to the determined quantity related to impedance in frequency interval D2.

According to a third aspect, a device, such as a transceiver unit or a tool is provided, which comprises an arrangement according to the second aspect.

According to a fourth aspect, a network node, such as a control or management node or tool is provided, which comprises an arrangement according to the second aspect.

According to a fifth aspect, a computer program is provided, which comprises computer readable code means, which when run in an arrangement or device according to any of the second, third or fourth aspect above, causes the arrangement and/or device to perform the corresponding method according to the first aspect above.

According to a sixth aspect, a computer program product is provided, which comprises the computer program according to the fifth aspect above.

The above method, arrangement, device; network node; computer program and/or computer program product may be used for estimating a quantity related to impedance in a first frequency interval, D1, of a telecommunication transmission line having a length d, where it may not otherwise be possible to determine a quantity related to impedance for various reasons. Further advantages which may be achieved is the enabling of e.g., retrieving of the characteristic impedance e.g. of the first segment of the transmission line with good accuracy; estimating the total line capacitance; determining the unknown character of load impedance or next segment input impedance; resolving of whether the line (end) is open or not; avoiding adverse phenomena such as ringing in the time domain or undesirable and indefinite time delays when transforming to time domain.

The above method, arrangement, device; network node; computer program and/or computer program product may be implemented in different embodiments. The Puiseux series may contain integer and/or half integer powers of frequency, and/or be represented by a Laurent or Taylor series with only even powers of the angular frequency in the real part and only odd powers of the angular frequency in the imaginary part.

Further, the quantity related to impedance may be estimated for a frequency f1_{D1} in the frequency interval D1, where the relation between the concerned frequencies (f1_{D1}, f1_{D2} and f2_{D2}) in the frequency intervals D1 and D2 is such that: max(abs(d*γ(f1)_{D2}−d*γ(f1)_{D1}), abs(d*γ(f2)_{D2}−d*γ(f1)_{D1}))<π.

Further, the first frequency interval D1 may comprise lower and/or higher frequencies than the second frequency interval D2. For example, D1 could comprise at least one frequency, which is lower than the lowest frequency in D2.

The estimating may further involve, in addition to the fitting of the Puiseux series, determining a function which is valid in D1, by use of the coefficients from the Puiseux series fitted to the determined quantity in frequency interval D2. The function may be e.g. a rational function or another Puiseux series, different from the Puiseux series fitted to the quantity determined in frequency interval D2. This may be performed e.g. when the fitted Puiseux series is not valid in, at least part of, frequency interval D1.

The determining may be based on an echo measurement performed in the first end of the transmission line or an impedance measurement performed in the first end of the transmission line; if assuming that the transmission line has a first and a second end.

Further, a smoothing function may be applied, in the frequency plane, to a transition region between determined (in D2) and estimated (in D1) values. The transition region may be a frequency region where the first frequency interval D1 and the second frequency interval D2 overlap. The smoothing function may be a linear combination of determined and estimated values, where the estimated values are given a higher weight in one end of the transition region, and lower weight in the other end of the transition region.

Further, a SELT postprocessing (SELT-P) may be performed on the transmission line, which SELT-P involves a transformation of a quantity related to the estimated impedance in the first frequency interval D1 between a frequency plane and a time plane, which transformation involves the applying of a windowing function centered approximately around f=0, or, starting approximately at f=0

The embodiments above have mainly been described in terms of a method. However, the description above is also intended to embrace embodiments of the arrangement, device, network node, computer program and computer program product configured to enable the performance of the above described features. The different features of the exemplary embodiments above may be combined in different ways according to need, requirements or preference.

### BRIEF DESCRIPTION OF THE DRAWINGS

The foregoing and other objects, features, and advantages of the technology disclosed herein will be apparent from the following more particular description of preferred embodiments as illustrated in the accompanying drawings.

FIG. 1 is a diagram showing a true (solid line) and an estimated (broken line) real part of the input impedance for 100 m AWG26 terminated with a short-circuit. The estimation being performed according to an exemplifying embodiment.

FIG. 2 is a diagram showing a true (solid line) and an estimated (broken line) imaginary part of the input impedance for 100 m AWG26 terminated with a short-circuit. The estimation being performed according to an exemplifying embodiment.

FIG. 3 is a diagram showing a comparison of frequency domain filters (Blackman windows) that can be applied to determined and estimated data before an Inverse Fast Fourier Transform.

FIG. 4 is a diagram showing the time domain (impulse) response of the three different filters illustrated in FIG. 3.

FIG. 5 is a diagram showing echo impulse response versus distance for 100 m AWG26 terminated with a short-circuit. The dotted line representing extrapolated Zᵢₙ according to an exemplifying embodiment of the invention is overlapping the response based on true Zᵢₙ. A prior art technique based on zero padding of the input reflection (or scattering parameter S₁₁) is illustrated by a broken line and shows substantial “ringing”. System impedance Z₀=100 Ω.

FIG. 6 is a flow chart illustrating actions of a procedure according to an exemplifying embodiment.

FIGS. 7-10 are block charts illustrating arrangements and/or devices according to exemplifying embodiments.

### DETAILED DESCRIPTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. That is, those skilled in the art will be able to devise various arrangements which, although not explicitly described or shown herein, embody the principles of the invention and are included within its spirit and scope. In some instances, detailed descriptions of well-known devices, circuits, and methods are omitted so as not to obscure the description of the present invention with unnecessary detail. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, e.g., any elements developed that perform the same function, regardless of structure.

Thus, for example, it will be appreciated by those skilled in the art that block diagrams herein can represent conceptual views of illustrative circuitry or other functional units embodying the principles of the technology. Similarly, it will be appreciated that any flow charts, state transition diagrams, pseudo code, and the like represent various processes which may be substantially represented in computer readable medium and so executed by a computer or processor, whether or not such computer or processor is explicitly shown.

The functions of the various elements including functional blocks, including but not limited to those labeled or described as “computer”, “processor” or “controller”, may be provided through the use of hardware such as circuit hardware and/or hardware capable of executing software in the form of coded instructions stored on computer readable medium. Thus, such functions and illustrated functional blocks are to be understood as being either hardware-implemented and/or computer-implemented, and thus machine-implemented.

In terms of hardware implementation, the functional blocks may include or encompass, without limitation, digital signal processor (DSP) hardware, reduced instruction set processor, hardware (e.g., digital or analog) circuitry including but not limited to application specific integrated circuit(s) (ASIC), and (where appropriate) state machines capable of performing such functions.

Regarding the notation within this description, the parameters R, L, C, G and Γ (Gamma) comprise the total line length d, and may depend on the angular frequency ω. For example, the notation “R” represents the total line resistance; the notation “L” represents the total line inductance; “Γ”=γ*d, etc., where γ is the so-called propagation constant.

Input impedance, Zin, of a transmission line of length d can be written in a number of different ways, e.g.

$$\begin{matrix}{Z}_{in} = {Z}_{C} \frac{{e}^{Γ} + {ρe}^{- Γ}}{{e}^{Γ} - {ρe}^{- Γ}} & ( 1 ) \\ = {Z}_{C} coth ( Γ - \frac{1}{2} ln ( ρ ) ) & ( 2 ) \\ = {Z}_{C} tanh ( Γ - \frac{1}{2} ln ( - ρ ) ) & ( 3 ) \\ = {Z}_{c} \frac{1 + {ρe}^{- 2 Γ}}{1 - {ρe}^{- 2 Γ}} & ( 4 ) \\ = {Z}_{C} ( 1 + \frac{2 {ρe}^{- 2 Γ}}{1 - {ρe}^{- 2 Γ}} ) & ( 5 )\end{matrix}$$

$$where {Z}_{C} = \sqrt{\frac{R + jω L}{G + jω C}} and Γ = γ d = \sqrt{( R + jω L ) ( G + jω C )}$$

are the line's characteristic impedance and propagation “constant” respectively (according to the solution of the Telegrapher's equation);

$$ρ = \frac{{Z}_{T} - {Z}_{C}}{{Z}_{T} + {Z}_{C}}$$

is the reflection coefficient at the end of the transmission line, and Z_{T} is the termination impedance, which in turn may be a lumped impedance (e.g. a capacitance and/or resistance) and/or a distributed impedance such as the input impedance of another transmission line.

As previously mentioned, it should be noted that the parameters R, L, C, G here include the length of the transmission line and may depend on the angular frequency ω=2πf. Depending on which frequency region that is of interest, this may have to be taken into account in series expansions. Resistance R is approximately constant below the so-called skin-effect region, which for common twisted-pair cables may start above say 30-300 kHz (higher values for thinner cables such as 0.3 mm wire diameter and lower values for thicker cables such as 0.9 mm). Inductance L is also approximately constant below the skin-effect region.

For many common cables, capacitance C can be regarded as frequency independent while the conductance G is often neglected (e.g. for Polyethylene insulation). For insulators where G cannot be neglected (e.g. paper or PVC), a common model of the conductance is G=ωC tan δ, i.e. the capacitive reactance times a dielectric loss factor (the so-called loss tangent). To be strict, the model for G should use the absolute value of the angular frequency, since conductance must be an even function (symmetrical with respect to zero frequency) in order to guarantee a real time-domain response.

The applicants have realized that, since the coth(x) function has a Laurent series expansion for small x

$$coth ( x ) = \frac{1}{x} + \frac{x}{3} - \frac{{x}^{3}}{45} + \frac{2 {x}^{5}}{945} - \frac{{x}^{7}}{4725} + …$$

and tan h(x) has a Taylor series expansion for small x,

$$tanh ( x ) = x - \frac{{x}^{3}}{3} + \frac{2 {x}^{5}}{15} - \frac{17 {x}^{7}}{315} + \frac{62 {x}^{9}}{2835} - …$$

it could be possible to approximate the input impedance, Zᵢₙ, with a series as well, given that the argument to the hyperbolic function is sufficiently small. This is further discussed in the patent application PCT/SE2005/001619 with publication number WO2007/050001 A1, which is hereby incorporated by reference in its entirety.

When setting out to derive a useful approximation of the input impedance in form of a series, the applicants have further realized that the following series expansion may be useful:

$$ln ( \frac{1 - x}{1 + x} ) = - 2 x - \frac{2 {x}^{3}}{3} - \frac{2 {x}^{5}}{5} - \frac{2 {x}^{7}}{7} - … for - 1 < x < 1$$

The applicants have further realized that there are some different cases that may need separate attention. These different cases and the findings for said cases will be described below.

### Case 1: Small Γ and High-Impedance Termination (Z_{T}>>Z_{C})

For the case with high-impedance termination of a transmission line or DUT, the reflection coefficient ρ is close to 1, (since

$$ρ = \frac{{Z}_{T} - {Z}_{C}}{{Z}_{T} + {Z}_{C}} ) ,$$

which means that the logarithm, ln(ρ), e.g. in expression (2) above, is close to 0, which in turn (together with a small Γ) ensures that the argument to coth( ) is also small (c.f. expression (2) above). Thus, since the coth(x) function has a Laurent series expansion for small arguments, the input impedance Zᵢₙ divided by the characteristic impedance Z_{C} can be series expanded as:

$$coth ( Γ - \frac{1}{2} ln ( ρ ) ) = \frac{1}{Γ - \frac{1}{2} ln ( ρ )} + \frac{Γ - \frac{1}{2} ln ( ρ )}{3} - \frac{{( Γ - \frac{1}{2} ln ( ρ ) )}^{3}}{45} + \frac{2 {( Γ - \frac{1}{2} ln ( ρ ) )}^{5}}{945} - \frac{{( Γ - \frac{1}{2} ln ( ρ ) )}^{7}}{4725} + …$$

Here, the logarithm of the reflection coefficient, p, can be rewritten and series expanded as

$$\begin{matrix}- \frac{1}{2} ln ( ρ ) = - \frac{1}{2} ln ( \frac{{Z}_{T} - {Z}_{C}}{{Z}_{T} + {Z}_{C}} ) \\ = - \frac{1}{2} ln ( \frac{1 - \frac{{Z}_{C}}{{Z}_{T}}}{1 + \frac{{Z}_{C}}{{Z}_{T}}} ) \\ = \frac{{Z}_{C}}{{Z}_{T}} + \frac{1}{3} {( \frac{{Z}_{C}}{{Z}_{T}} )}^{3} + \frac{1}{5} {( \frac{{Z}_{C}}{{Z}_{T}} )}^{5} + \frac{1}{7} {( \frac{{Z}_{C}}{{Z}_{T}} )}^{7} + …\end{matrix}$$

Putting the above together and ignoring all terms with powers of

$$\frac{{Z}_{C}}{{Z}_{T}}$$

higher than one (more terms can be included if desired) in the binomial expansion gives:

$$\begin{matrix}\frac{{Z}_{in}}{{Z}_{C}} = \frac{1}{Γ + \frac{{Z}_{C}}{{Z}_{T}}} + \frac{Γ + \frac{{Z}_{C}}{{Z}_{T}}}{3} - \frac{{( Γ + \frac{{Z}_{C}}{{Z}_{T}} )}^{3}}{45} + \\ \frac{2 {( Γ + \frac{{Z}_{C}}{{Z}_{T}} )}^{5}}{945} - \frac{{( Γ + \frac{{Z}_{C}}{{Z}_{T}} )}^{7}}{4725} + … \\ \approx \frac{1}{Γ + \frac{{Z}_{C}}{{Z}_{T}}} + \frac{Γ + \frac{{Z}_{C}}{{Z}_{T}}}{3} - \frac{{Γ}^{3} + 3 {Γ}^{2} \frac{{Z}_{C}}{{Z}_{T}}}{45} + \\ \frac{2 {Γ}^{5} + 10 {Γ}^{4} \frac{{Z}_{C}}{{Z}_{T}}}{945} - \frac{{Γ}^{7} + 7 {Γ}^{6} \frac{{Z}_{C}}{{Z}_{T}}}{4725} + …\end{matrix}$$

$$Thus , \\ {Z}_{in} \approx \frac{1}{\frac{Γ}{{Z}_{C}} + \frac{1}{{Z}_{T}}} + \frac{{Z}_{C} Γ + \frac{{Z}_{C}^{2}}{{Z}_{T}}}{3} - \frac{{Z}_{C} {Γ}^{3} + \frac{3 {Z}_{C}^{2} {Γ}^{2}}{{Z}_{T}}}{45} + \frac{2 {Z}_{C} {Γ}^{5} + \frac{10 {Z}_{C}^{2} {Γ}^{4}}{{Z}_{T}}}{945} - \frac{{Z}_{C} {Γ}^{7} + \frac{7 {Z}_{C}^{2} {Γ}^{6}}{{Z}_{T}}}{4725} + …$$

which in turn becomes:

$${Z}_{in} \approx \frac{1}{G + j ω C + \frac{1}{{Z}_{T}}} + \frac{1}{3} ( R + j ω L + \frac{R + j ω L}{{Z}_{T} ( G + j ω C )} ) - \frac{1}{45} ( {( R + j ω L )}^{2} ( G + j ω C ) + \frac{3 {( R + j ω L )}^{2}}{{Z}_{T}} ) + \frac{2}{945} ( {( R + j ω L )}^{3} {( G + j ω C )}^{2} + \frac{5 {( R + j ω L )}^{3} ( G + j ω C )}{{Z}_{T}} ) - \frac{1}{4725} ( {( R + j ω L )}^{4} {( G + j ω C )}^{3} + \frac{7 {( R + j ω L )}^{4} {( G + j ω C )}^{2}}{{Z}_{T}} ) + …$$

The above expression is a mix of series and rational functions, which complicates fitting to measured data. The first term shows that a simple approximation of the input impedance is the termination impedance in parallel with G and C (sum of admittances).

If the conductance G can be neglected (true for many telephony cables), the expansion of the input impedance can be written as a sum of a rational function and a Taylor series:

$${Z}_{in} \approx \frac{1}{j ω C + \frac{1}{{Z}_{T}}} + \frac{1}{3} ( R + j ω L + \frac{R + j ω L}{{Z}_{T} j ω C} ) - \frac{1}{45} ( {( R + j ω L )}^{2} j ω C + \frac{3 {( R + j ω L )}^{2}}{{Z}_{T}} ) + \frac{2}{945} ( {( R + j ω L )}^{3} {( j ω C )}^{2} + \frac{5 {( R + j ω L )}^{3} j ω C}{{Z}_{T}} ) - \frac{1}{4725} ( {( R + j ω L )}^{4} {( j ω C )}^{3} + \frac{7 {( R + j ω L )}^{4} {( j ω C )}^{2}}{{Z}_{T}} ) + …$$

Thanks to the inclusion of this rational function, it is possible to accurately estimate e.g. the input impedance at and near zero frequency for cases with non-negligible high-impedance load, which was not possible, and not the purpose, using the prior art series expansion [PCT/SE2005/001619]. Correct input impedance at and near DC is very important e.g. when it is desired to perform low-pass time-domain analysis. It should be noted that the above expression differs from the series expansion for non-negligible load (termination impedance) in the incorporated prior art document PCT/SE2005/001619. The applicants have found that the prior art expression for non-negligible load (neither zero nor infinite) was only valid for Z_{T}<Z_{C}. For example, if the real part of the termination impedance is on the order of kΩ or higher (but not infinite), the prior art expression estimates the frequency independent part of input impedance as R+Z_{T} while the correct value is

$$\frac{R}{3}$$

(as estimated by the expression in the current invention). Further, at zero frequency, the prior art expression will estimate the real part as Z_{T}, while the expression in the current invention estimates the true value of

$$\frac{R}{3} + {Z}_{T} .$$

If the termination impedance is purely capacitive, the rational function is not needed and the above expression becomes a Laurent series in ω. If instead the termination impedance is purely resistive, the first term in the above expression is a rational function while the remaining part can be described by a Taylor series in ω. For frequencies where

$$\vert ω C \vert > \frac{1}{{Z}_{T}} ,$$

and assuming that the termination impedance is real (any imaginary part can be included in jωC), the rational function can further be expanded as

$$Q ( f ) = \frac{1}{j ω C + \frac{1}{{Z}_{T}}} = \frac{\frac{1}{{Z}_{T}} - j ω C}{\frac{1}{{Z}_{T}^{2}} + {( ω C )}^{2}} \approx \frac{\frac{1}{{Z}_{T}} - j ω C}{{( ω C )}^{2}} = \frac{1}{{Z}_{T} {ω}^{2} {C}^{2}} - \frac{j}{ω C}$$

which is also a Laurent series. It should however be noted that this last approximation is not valid near DC since the rational function becomes equal to the real part of the termination impedance at DC while the approximation goes to infinity. Thus, if the impedance should be extrapolated down to DC, fitting can be performed on the approximation of the rational function Q(f), but for the extrapolation near or at DC, it is preferred to reconstruct the rational function based on the information from the fitting. For example, if a Laurent series of the form:

$$\frac{{a}_{- 2}}{{ω}^{2}} + \frac{{a}_{- 1} j}{ω} + {a}_{0} + {a}_{1} j ω + {a}_{2} {ω}^{2} + {a}_{1} j {ω}^{3} + …$$

is fitted to the input impedance in this case, the result will be:

$$\begin{matrix}\begin{matrix}{a}_{- 2} = \frac{1}{{Z}_{T} {C}^{2}} \\ {a}_{- 1} = - \frac{1}{C}\end{matrix} \\ {a}_{0} = …\end{matrix} \} ⇒ Q ( f ) = \frac{1}{\frac{ω}{j {a}_{- 1}} + \frac{{a}_{- 2}}{{( {a}_{- 1} )}^{2}}} = \frac{1}{jω C + \frac{1}{{Z}_{T}}}$$

Note that the first term

$$( \frac{{a}_{- 2}}{{ω}^{2}} )$$

in this series expansion was not included in the prior art [PCT/SE2005/001619] (where it was not relevant or needed) but here, it is essential in order to correctly enable performing of low-pass time-domain analysis for transmission lines terminated with non-negligible loads. As can be seen, it is possible to use the information from the series fitting in one frequency interval to reconstruct a function (here a rational function) that is valid in the extrapolation interval (and in this case also in the fitting interval). One advantage of the proposed method is that the fitting can still be performed using well-known Linear Least-Squares methods (on Laurent series) despite the fact that a rational function is involved in the estimation.

For more complicated termination impedances, other expansions than Laurent series may be needed, such as e.g. Puiseux series. The term “Puiseux series” is used within this document as to also embrace e.g. Laurent series and Taylor series, which may be regarded as sub-sets of Puiseux series.

Further, if the termination can be regarded as infinite (open-end) and conductance is still negligible, the input impedance can be approximated as

$$\begin{matrix}{Z}_{in} \approx \frac{1}{j ω C} + \frac{1}{3} ( R + j ω L ) - \frac{1}{45} ( {( R + j ω L )}^{2} j ω C ) + \\ \frac{2}{945} ( {( R + j ω L )}^{3} {( j ω C )}^{2} ) - \frac{1}{4725} ( {( R + j ω L )}^{4} {( j ω C )}^{3} ) + … \\ = \frac{1}{j ω C} + \frac{R}{3} + ( \frac{L}{3} - \frac{{R}^{2} C}{45} ) jω + ( \frac{2 R L C}{45} - \frac{2 {R}^{3} {C}^{2}}{945} ) {ω}^{2} + \\ ( \frac{{L}^{2} C}{45} - \frac{2 {R}^{2} L {C}^{2}}{315} + \frac{2 {R}^{4} {C}^{3}}{4725} ) j {ω}^{3} + …\end{matrix}$$

which corresponds to fitting a Laurent series of the form

$$\frac{{a}_{- 1} j}{ω} + {a}_{0} + {a}_{1} j ω + {a}_{2} {ω}^{2} + {a}_{1} j {ω}^{3} + …$$

In this case, it can be seen that the real part of the input impedance can be described by using only even powers of ω while the imaginary part contains only odd powers of ω. For reasons of numerical stability (e.g. in presence of noise or limited precision in numerical calculations), this should preferably be taken into account when fitting a series to the measured data. To further improve numerical stability, it can be observed from the above that when using the above Laurent series, the a₋₁ coefficient must be negative. If not, it is an indication that this series expansion is not valid for the current measurement.

Finally, it should be noted that if conductance is non-negligible, the real part of the input impedance may contain non-zero coefficients for odd powers of the absolute value of the angular frequency, e.g. |ω|,|ω³|, and the imaginary part may contain coefficients for even powers of the absolute value times the sign, e.g.

$$\frac{\vert ω \vert}{ω} = sgn ( w ) , \vert ω \vert \cdot ω = {w}^{2} sgn ( w ) .$$

However, at least for many common telephone cables, the error due to neglecting the conductance is small. Also, due to reasons of numerical stability mentioned above, it is preferred to use only even powers for the real part and odd powers for the imaginary part.

### Case 2: Small Γ and Low-Impedance Termination (Z_{T}<<Z_{C})

For the case with low-impedance termination, the reflection coefficient ρ is close to −1, which means that the logarithm ln(ρ) is close to jπ. Here, it may instead be preferred to series expand the hyperbolic tangent (c.f. expression (3) above) since for a reflection coefficient close to −1, ln(−ρ) is close to zero, which together with a small Γ means that the argument to tan h( ) will be small. Thus, the input impedance Zᵢₙ divided by the characteristic impedance Z_{c} can be expanded as:

$$tanh ( Γ - \frac{1}{2} ln ( - ρ ) ) = Γ - \frac{1}{2} ln ( - ρ ) - \frac{{( Γ - \frac{1}{2} ln ( - ρ ) )}^{3}}{3} + \frac{2 {( Γ - \frac{1}{2} ln ( - ρ ) )}^{3}}{15} - \frac{17 {( Γ - \frac{1}{2} ln ( - ρ ) )}^{7}}{315} + \frac{62 {( Γ - \frac{1}{2} ln ( - ρ ) )}^{9}}{2835} - …$$

In this case, the logarithm of the reflection coefficient can be rewritten and series expanded as

$$- \frac{1}{2} ln ( - ρ ) = - \frac{1}{2} ln ( - \frac{{Z}_{T} - {Z}_{C}}{{Z}_{T} + {Z}_{C}} ) = - \frac{1}{2} ln ( \frac{1 - \frac{{Z}_{T}}{{Z}_{C}}}{1 + \frac{{Z}_{T}}{{Z}_{C}}} ) = \frac{{Z}_{T}}{{Z}_{C}} + \frac{1}{3} {( \frac{{Z}_{T}}{{Z}_{C}} )}^{5} + \frac{1}{7} {( \frac{{Z}_{T}}{{Z}_{C}} )}^{7} + …$$

Putting the above together and ignoring all terms with powers of

$$\frac{{Z}_{T}}{{Z}_{C}}$$

higher than one (more terms can be included if desired) gives

$$\frac{{Z}_{in}}{{Z}_{C}} \approx Γ + \frac{{Z}_{T}}{{Z}_{C}} - \frac{{( Γ + \frac{{Z}_{T}}{{Z}_{C}} )}^{3}}{3} + \frac{2 {( Γ + \frac{{Z}_{T}}{{Z}_{C}} )}^{5}}{15} - \frac{17 {( Γ + \frac{{Z}_{T}}{{Z}_{C}} )}^{7}}{315} + \frac{62 {( Γ + \frac{{Z}_{T}}{{Z}_{C}} )}^{9}}{2835} - … \approx Γ + \frac{{Z}_{T}}{{Z}_{C}} - \frac{{Γ}^{3} + 3 {Γ}^{2} \frac{{Z}_{T}}{{Z}_{C}}}{3} + \frac{2 ( {Γ}^{5} + 5 {Γ}^{4} \frac{{Z}_{T}}{{Z}_{C}} )}{15} - \frac{17 ( {Γ}^{7} + 7 {Γ}^{6} \frac{{Z}_{T}}{{Z}_{C}} )}{315} + \frac{62 ( {Γ}^{9} + 9 {Γ}^{8} \frac{{Z}_{T}}{{Z}_{C}} )}{2835} - …$$

$$Thus \text{:}$$

$${Z}_{in} \approx {Z}_{C} Γ + {Z}_{T} - \frac{{Z}_{C} {Γ}^{3} + 3 {Γ}^{2} {Z}_{T}}{3} + \frac{2 ( {Z}_{C} {Γ}^{5} + 5 {Γ}^{4} {Z}_{T} )}{15} - \frac{17 ( {Z}_{C} {Γ}^{7} + 7 {Γ}^{6} {Z}_{T} )}{315} + \frac{62 ( {Z}_{C} {Γ}^{9} + 9 {Γ}^{8} {Z}_{T}}{2835} - …$$

which becomes:

$${Z}_{in} \approx R + j ω L + {Z}_{T} - \frac{{( R + j ω L )}^{2} ( G + j ω C ) + 3 ( R + j ω L ) ( G + j ω C ) {Z}_{T}}{3} + \frac{2 ( {( R + j ω L )}^{3} {( G + j ω C )}^{2} + 5 {( R + j ω L )}^{2} {( G + j ω C )}^{2} {Z}_{T} )}{15} - \frac{17 ( {( R + j ω L )}^{4} {( G + j ω C )}^{3} + 7 {( R + j ω L )}^{3} {( G + j ω C )}^{3} {Z}_{T} )}{315} + \frac{62 ( {( R + jω L )}^{5} {( G + j ω C )}^{4} + 9 {( R + j ω L )}^{3} {( G + j ω C )}^{3} {Z}_{T} )}{2835} - …$$

Neglecting the conductance G gives

$${Z}_{in} \approx R + j ω L + {Z}_{T} - \frac{{( R + j ω L )}^{2} j ω C + 3 ( R + j ωL ) jω {CZ}_{T}}{3} + \frac{2 ( {( R + j ω L )}^{3} {( j ω C )}^{2} + 5 {( R + j ω L )}^{2} {( j ω C )}^{2} {Z}_{T} )}{15} - \frac{17 ( {( R + j ω L )}^{4} {( j ω C )}^{3} + 7 {( R + j ω L )}^{3} {( j ω C )}^{3} {Z}_{T} )}{315} + \frac{62 ( {( R + j ω L )}^{5} {( j ω C )}^{4} + 9 {( R + j ω L )}^{3} {( j ω C )}^{3} {Z}_{T} )}{2835} - …$$

Further, if the termination impedance Z_{T} is zero (short-circuit) the input impedance reduces to

$${Z}_{in} \approx R + j ω L - \frac{{( R + j ω L )}^{2} j ω C}{3} + \frac{2 {( R + j ω L )}^{3} {( j ω C )}^{2}}{15} - \frac{17 {( R + j ω L )}^{4} {( j ω C )}^{3}}{315} + \frac{62 {( R + j ω L )}^{5} {( j ω C )}^{4}}{2835} - … \approx R + ( L - \frac{{R}^{2} C}{3} ) j ω + ( \frac{2 RLC}{3} - \frac{2 {R}^{3} {C}^{2}}{15} ) {ω}^{2} + ( \frac{{L}^{2} C}{3} - \frac{2 {R}^{2} {LC}^{2}}{5} + \frac{17 {R}^{4} {C}^{3}}{315} ) j {ω}^{3} ++ ( \frac{2 {RC}^{2} {L}^{2}}{5} - \frac{68 {R}^{3} {LC}^{3}}{315} + \frac{62 {R}^{5} {C}^{4}}{2835} ) {ω}^{4} + …$$

where it, in the same way as for the high-impedance case, can be observed that the real part of the input impedance only contains even powers of the angular frequency and that the imaginary part only contains odd powers.

### Case 3: Small Γ and Nearly Matched Termination (Z_{T}≈Z_{C})

When the termination impedance Z_{T} is almost matched to the characteristic impedance Z_{C}, which could happen e.g. if a second transmission line with similar properties is connected at the end of the first transmission line, the above approximations are no longer valid. In this case, another expression for the input impedance Zᵢₙ (c.f. expression (5) above) has been found more suitable for expansion into a Taylor (Maclaurin) series in ρ:

$${Z}_{in} = {Z}_{C} ( 1 + \frac{2 ρ {e}^{- 2 Γ}}{1 - ρ {e}^{- 2 Γ}} ) = {Z}_{C} ( 1 + \frac{2 ρ}{{e}^{2 Γ} - ρ} ) \approx {Z}_{C} ( 1 + \frac{2 ρ}{{e}^{2 Γ}} + \frac{2 {ρ}^{2}}{{e}^{4 Γ}} + \frac{4 {ρ}^{3}}{{e}^{6 Γ}} + … )$$

Applying the series expansion for

$${e}^{- 2 Γ} = 1 + ( - 2 Γ ) + \frac{{( - 2 Γ )}^{2}}{2} + \frac{{( - 2 Γ )}^{3}}{6} + \frac{{( - 2 Γ )}^{4}}{24} + …$$

and truncating high-order terms gives:

$$\begin{matrix}{Z}_{in} \approx {Z}_{C} ( 1 + 2 ρ - 4 ρ Γ + 4 {ρΓ}^{2} - \frac{8 {ρΓ}^{3}}{3} + \frac{4 {ρΓ}^{4}}{3} - … ) \\ = {Z}_{C} ( 1 + 2 ρ ) - 4 ρ {Z}_{C} Γ + 4 ρ {Z}_{C} {Γ}^{2} - \frac{8 ρ {Z}_{C} {Γ}^{3}}{3} + \frac{4 ρ {Z}_{C} {Γ}^{4}}{3} - … \\ = \sqrt{\frac{R + j ω L}{G + j ω C}} ( 1 + 2 ρ ) - 4 ρ ( R + j ω L ) + \\ 4 {ρ ( R + jω L )}^{\frac{3}{2}} {( G + jω C )}^{\frac{1}{2}} - \\ \frac{8 {ρ ( R + j ω L )}^{2} ( G + j ω C )}{3} + \frac{4 {ρ ( R + j ω L )}^{\frac{5}{2}} {( G + j ω C )}^{\frac{3}{2}}}{3} - …\end{matrix}$$

which can be expanded using e.g. Newton's generalized binomial theorem If, again for simplicity, conductance G is assumed to be negligible, we get

$${Z}_{in} \approx \sqrt{\frac{R + j ω L}{j ω C}} ( 1 + 2 ρ ) - 4 ρ ( R + j ω L ) + 4 {ρ ( R + j ω L )}^{\frac{3}{2}} {( jω C )}^{\frac{1}{2}}$$

For small absolute values of the reflection coefficient, the input impedance will here be dominated by the characteristic impedance Z_{c}. Now, if

$$\vert ω \vert < \frac{R}{L} ,$$

the characteristic impedance (neglecting conductance) can be expanded as

$$\begin{matrix}\sqrt{\frac{R + j ω L}{j ω C}} = \sqrt{\frac{R}{j ω C}} \sqrt{1 + \frac{j ω L}{R}} \approx \sqrt{\frac{R}{j ω C}} \\ ( 1 + \frac{j ω L}{2 R} - \frac{1}{8} {( \frac{j ω L}{R} )}^{2} + \frac{1}{16} {( \frac{j ω L}{R} )}^{3} - \\ \frac{5}{128} {( \frac{j ω L}{r} )}^{4} + … ) \\ = ( 1 - j ) \sqrt{\frac{R}{2 ω C}} ( 1 + \frac{j ω L}{2 R} - \frac{1}{8} {( \frac{j ω L}{R} )}^{2} + \frac{1}{16} {( \frac{j ω L}{R} )}^{3} - \\ \frac{5}{128} {( \frac{j ω L}{R} )}^{4} + … ) \\ = ( 1 - j ) \sqrt{\frac{R}{2 ω C}} ( 1 + \frac{j ω L}{2 R} + \frac{1}{8} {( \frac{j ω L}{R} )}^{2} + \frac{1}{16} {( \frac{j ω L}{R} )}^{3} + \\ \frac{5}{128} {( \frac{ω L}{R} )}^{4} + … )\end{matrix}$$

which is a Puiseux series in jω since fractional powers are involved and since R can typically be regarded as constant in the frequency region where the assumption

$$\vert ω \vert < \frac{R}{L}$$

is valid. For AWG26 telephone cable, this would mean approximately f<70 kHz, which is close to subcarrier 16 in e.g. ADSL. For thicker cables, this limit is typically even lower. At least for thicker cables, typical xDSL transceivers may not be able to measure echo or determine impedance (with sufficient accuracy) in the region where this approximation is valid.

An example of a Puiseux series in jω valid for the complex input impedance in this case is

$${{a}_{- 0.5} ( j ω )}^{- 0.5} + {{a}_{0.5} ( j ω )}^{0.5} + …$$

$$where$$

$${a}_{- 0.5} = \sqrt{\frac{R}{C}} {a}_{0.5} = \frac{L}{2 \sqrt{RC}}$$

For this case, it can be observed that, since e.g.

$${j}^{- 0.5} = \pm \frac{1 - j}{\sqrt{2}} , {j}^{0.5} = \pm \frac{1 + j}{\sqrt{2}} ,$$

a series expansion of the real part of the input impedance will give coefficients with the same magnitude (but possibly different sign) as a series expansion of the imaginary part of the input impedance. Thus, if fitting is performed separately on the real and imaginary parts of the input impedance using another Puiseux series now in ω instead of jω

a_{0.5}ω^{-0.5}+a_{0.5}ω^{0.5}+ . . .

then this case can be identified if the magnitude of corresponding coefficients for the real and imaginary part are within some threshold, e.g. 1% or 10%. Once the case has been identified, accuracy and numerical stability could, if desired, be improved by fitting the Puiseux series in jω to the complex input impedance instead of performing separate fits for real and imaginary parts.

Alternatively, if

$$\vert ω \vert > \frac{R}{L} ,$$

Z_{c} can be series expanded as

$$\begin{matrix}\sqrt{\frac{R + jω L}{jω C}} = \sqrt{\frac{L}{C}} \sqrt{1 + \frac{R}{jω L}} \\ \approx \sqrt{\frac{L}{C}} ( 1 + \frac{R}{2 jω L} - \frac{1}{8} {( \frac{R}{jω L} )}^{2} + \frac{1}{16} {( \frac{R}{jω L} )}^{3} - … ) \\ = \sqrt{\frac{L}{C}} ( 1 - \frac{j R}{2 ω L} - \frac{1}{8} {( - \frac{j R}{ω L} )}^{2} + \frac{1}{16} {( - \frac{j R}{ω L} )}^{3} - … )\end{matrix}$$

which, if R, L, C can be regarded as constants, can be expanded as

$${b}_{0} + {b}_{- 1} {jω}^{- 1} + {b}_{- 2} {ω}^{- 2} + {b}_{- 3} {jω}^{- 3} + …$$

$$where$$

$${b}_{0} = \sqrt{\frac{L}{C}} \\ {b}_{- 1} = - \frac{R}{2 \sqrt{LC}} \\ {b}_{- 2} = …$$

This series expansion shows similar behavior as Case 1 and 2 in that only even powers in ω are present in the real part and only odd powers in the imaginary part. The main difference is instead that no positive powers are present here. If it is desired to extrapolate impedance down to zero or very low frequencies, the current series expansion is not valid. However, the coefficients from the current series expansion allows calculation of the coefficients for the corresponding series expansion in the lower frequency interval

$$\vert ω \vert < \frac{R}{L}$$

as follows

$${a}_{- 0.5} = \sqrt{\frac{R}{C}} = \sqrt{- 2 {b}_{0} {b}_{- 1}}$$

$${a}_{0.5} = \frac{L}{2 \sqrt{RC}} = \sqrt{- \frac{{b}_{0}^{3}}{8 {b}_{- 1}}}$$

In other words, the information from fitting a Laurent series expansion valid in frequency interval D2 was converted to another function (Puiseux series) valid in another frequency interval D1 (very low frequencies) but not valid in D2.

### Summary of the Three Cases

One component in the solution described herein is the previously mentioned observation that, for many common types of termination impedances, the real part of input impedance contains only even powers of ω and the imaginary part of the input impedance contains only odd powers of ω. One exception is for Case 3 when

$$\vert ω \vert < \frac{R}{L}$$

but typically, for DSL systems and for the frequencies where this is valid, it is not possible to measure input impedance with sufficient accuracy. Therefore, the coefficients with fractional powers of ω can usually be omitted from the fitting (but may be needed during extrapolation).

An example of a series expansion that covers most cases of interest is

a₋₂ω⁻²+a₋₁ω⁻¹+a₀+a₁ω¹+a₂ω²+a₃ω³

Since this expansion contains three terms each for the real and imaginary part, it is necessary to measure or otherwise determine input impedance for at least three frequencies in order to perform fitting. If input impedance is available for more frequencies, accuracy of extrapolation may improve by including higher order (positive and/or negative) terms in the above expansion. If the input impedance is only available for two frequencies, one coefficient each has to be removed from the real and imaginary part of the series expansion. This can be done in a number of ways, e.g. utilizing information about termination (e.g. open/short) from prior art SELT methods [G.996.2], by removing the highest order terms and accepting lower accuracy in extrapolation, or by removing some terms and inspecting the fitted coefficients for the remaining terms in order to try to determine which type of termination is present.

Since physical systems are causal, they fulfill the Hilbert relation. This means that whereas real part of the input impedance at low frequencies may be obtained by extrapolating/estimating from measured data at higher frequencies, the imaginary part may be obtained using the Hilbert relation. The opposite is also true. Consequently, a conventional formulation of the least-squares problem as a polynomial fitting permits to solve, independently, normal equations for the real and imaginary parts of the input impedance. However, the error due to forcing Hilbert relations upon approximate models is a different cause of model imperfection. This error may be interpreted as another deviation from the “truth” and could be incorporated in the least-squares criterion and hence be minimized.

The normal equations can then be advantageously extended and interrelated by imposing a requirement that obtained real and imaginary parts are a Hilbert pair.

In practice, however, the Hilbert conditions cannot be fully satisfied due to various reasons. First, the polynomials applied do not necessarily meet the formal requirements for Hilbert transform. Secondly, they represent an approximate model in a certain frequency interval and therefore do not apply universally. Thirdly, the omnipresent measurement noise alters estimates unpredictably.

On the other hand, employing the Hilbert relations increases the number of equations by a factor of two; therefore the noise influence will be strongly reduced. The numerical cost is tolerable since the Hilbert transform is a multiplier operator, i.e. it can be performed as a matrix multiplication.

Another problem associated with the extension of the data towards lower and/or higher frequency is as follows. The modeling error (by which is meant the discrepancy between the assumed model and reality) may cause an abrupt jump (discontinuity) when measured data are extended by the extrapolated/estimated data. To mitigate this problem, a smoothing procedure may be introduced. Such smoothing could be implemented e.g. by a moving average filter or, utilizing any overlap in frequency between measured (determined) and extrapolated (estimated) values, by a properly designed linear combination between determined and extrapolated values.

For example, introducing a weighting function in the frequency domain, such as

Z(f)=V(f)·Z_{in,est}(f)+(1−V(f))·Z_{in,meas}(f) (6)

will result in a smoothing of the spectra in the frequency domain.

The function V(f) can be selected in a variety of ways, e.g.

$$V ( f ) = [ \begin{matrix}1 & f \leq {f}_{1} \\ \begin{matrix}tapering \\ function\end{matrix} & {f}_{1} \leq f \leq {f}_{2} \\ 0 & f \geq {f}_{2}\end{matrix} \qquad ( 7 )$$

where f₁ is the lowest measured frequency and f₂ is the highest frequency considered in series fitting and the tapering function may for instance be a linearly decreasing function, a raised cosine, or similar function that gives a smooth transition. In general, the choice of the tapering function and smoothing procedure can be customized from case to case.

While the series expansions in this description were determined for small Γ, with a convergence radius of |Γ|<π, it should be observed that, since coth( ) and tan h( ) are periodic functions, similar expansions could be made for larger Γ, e.g. by performing series expansion around |Γ|=2π instead of the current series expansion around |Γ|=0. Such expansions would of course no longer be valid down to zero frequency but could still be useful to extrapolate input impedance at higher frequencies.

### Method of the Invention

A preferred embodiment of the invention can be summarized in the following steps:
Determine a parameter (quantity) related to impedance for at least two frequencies in frequency interval D2.
If the determined parameter is not of the same type as the parameter for which series expansions have been made, convert either the determined parameter or the series expansion using known relations between different parameters (e.g. impedance, admittance, input reflection)
Select a proper series (e.g. Taylor, Laurent, Puiseux) to use for expansion, either by using any knowledge regarding the current termination, by trying a combination of series covering the cases of interest (e.g. open and short), or by trying different series one at a time checking which gives the best fit to data in D2.
Fit the selected series to the determined quantity
Extrapolate data to at least one frequency in frequency interval D1, either directly using the fitted series or by using the information from the fitted series to calculate another extrapolation function that is valid in D1, as previously described, e.g. determining the rational function for Case 1 above or using the coefficients of the fitted series to determine another series which is valid at and near zero frequency as in Case 3 above.
Optionally use a smoothing function to reduce any discontinuity between determined and extrapolated quantities. If D1 is at least partially overlapping D2, the output in the overlapping region is selected as a linear combination of the extrapolated parameter and the previously determined parameter. The linear combination weighting is preferably designed as a tapering function that minimizes any discontinuity in the final parameter.
Optionally convert the result to a parameter which is more suitable for time domain analysis and perform time-domain analysis (e.g. SELT-P), either using a band-pass filter or a low-pass filter in conjunction with an inverse Fourier transform or other suitable transform

By a “quantity related to impedance” is meant e.g. input impedance Zin; input reflection ρᵢₙ (rho_in); input scattering parameter S11 or input admittance Yin.

### Extrapolation of Results in Frequency Domain

For xDSL applications, the transceiver usually contains a high-pass filter in order to block underlying POTS or ISDN service on the same twisted pair. Also, the line transformer, which is needed for common mode signal rejection, acts as a high-pass filter. Restrictions may also apply on which subcarriers that can be used to transmit SELT signals. Together, this means that xDSL equipment, depending on configuration, typically cannot reliably measure the lowest 6 or sometimes even lowest 32 subcarriers. There are also receiver-based limitations regarding the highest possible subcarrier that can be used in SELT measurements. For example, some older DSLAMs can only perform SELT up to subcarrier 63.

The following exemplifying results are based on the assumption that it is possible to determine input impedance from subcarrier 32 up to subcarrier 255. The fitting is performed on subcarriers 32-42 (interval D2) and extrapolation is performed for subcarriers 0-42 (interval D1), using a linear tapering function to combine determined and extrapolated data for subcarrier 32-42. Here, no measurement was performed but input impedance was determined from a standard cable model.

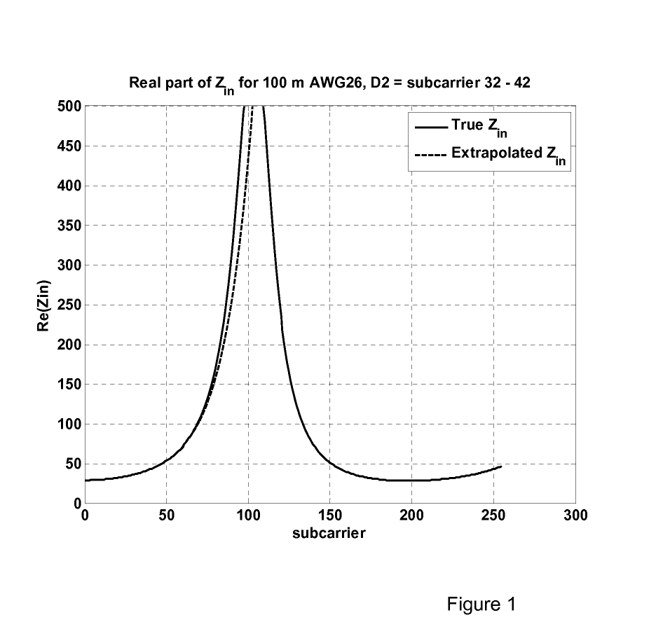

FIG. 1 shows the real part of the input impedance for a 100 meter long AWG26 cable, terminated by a short-circuit (Case 2 above). The fitting region D2 consists of xDSL subcarriers 32-42 (138-181 kHz). It can be seen that the extrapolated data is close to the true data up to at least subcarrier 80. Thus, in this case, it is possible to extrapolate both to lower frequencies (subcarrier 0-31) and to higher frequencies (subcarrier 43-80). If this is desired, D1 could encompass subcarriers 0-80. If only low-frequency extrapolation is desired, D1 could encompass e.g. subcarriers 0-31 (no overlap) or 0-42.

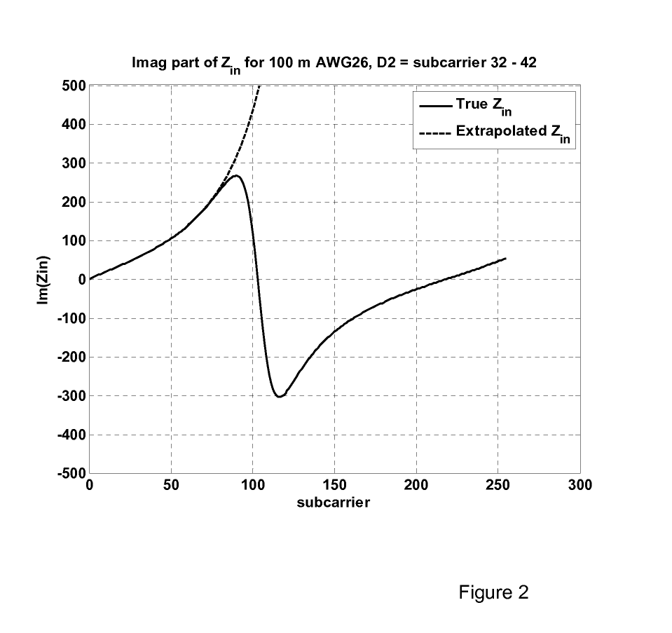

FIG. 2 shows the same situation for the imaginary part of the input impedance with a similar conclusion about possibility to extrapolate both to lower and to higher frequencies.

### Time-Domain Analysis

In general, it is possible to convert frequency domain data to time domain using e.g. an IFFT. Here, the input reflection coefficient is used:

$${ρ}_{in} = \frac{{Z}_{in} - {Z}_{0}}{{Z}_{in} + {Z}_{0}}$$

where the system impedance Z₀ may be e.g. 100Ω for xDSL applications.

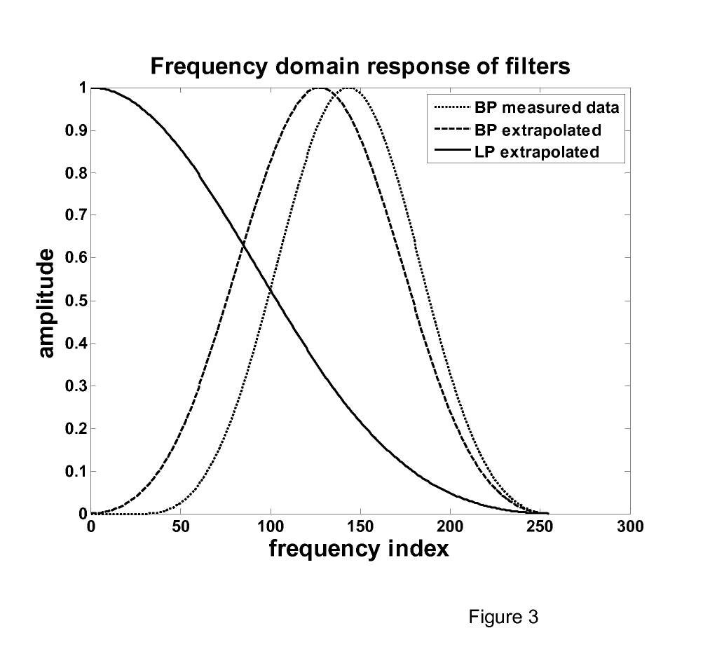

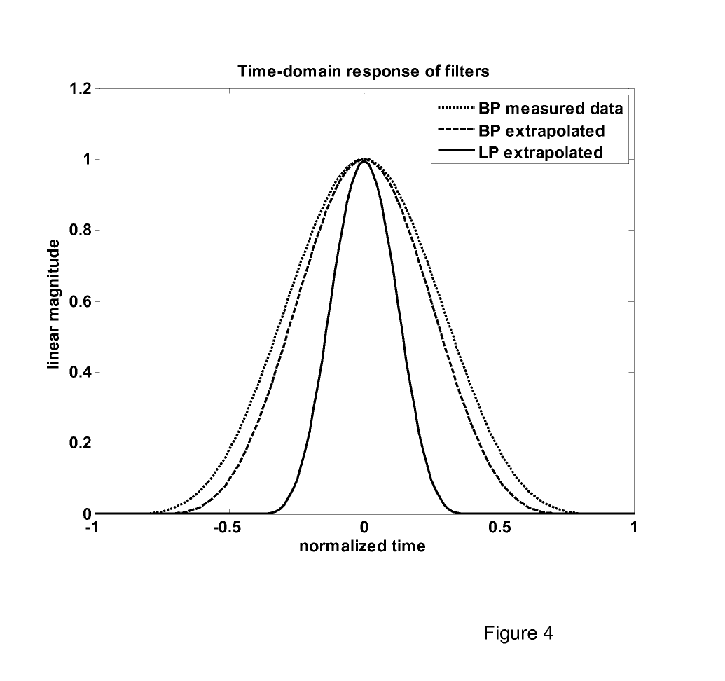

In general, a filter (window function) is needed when going from frequency to time domain in order to reduce ringing. Which window to use depends on the application, but common windows are e.g. Hamming, Hanning, and Blackman. Without extrapolation to lower frequencies, the window would have to be of band-pass (BP) type, starting at the first measurable frequency and ending at the last measurable frequency. The frequency response of a Blackman window with this assumption is shown in FIG. 3 (BP measured data). If proper extrapolation is performed, it is possible to either use a wider band-pass filter (e.g. as “BP extrapolated” shown in FIG. 3) or an even wider low-pass filter (c.f. LP extrapolated in FIG. 3). FIG. 4 shows the corresponding time domain (impulse) response for these three window functions where it can be seen, as expected, that the wider the frequency domain bandwidth, the narrower the impulse response. A narrow impulse response means improved time resolution. Some resolution benefit is already seen on the BP extrapolated data but a substantial improvement in resolution is shown for the LP extrapolated data. Since time is often translated to distance using the cable's velocity of propagation, this also means improved distance resolution, e.g. that two closely spaced impedance changes can be resolved better.

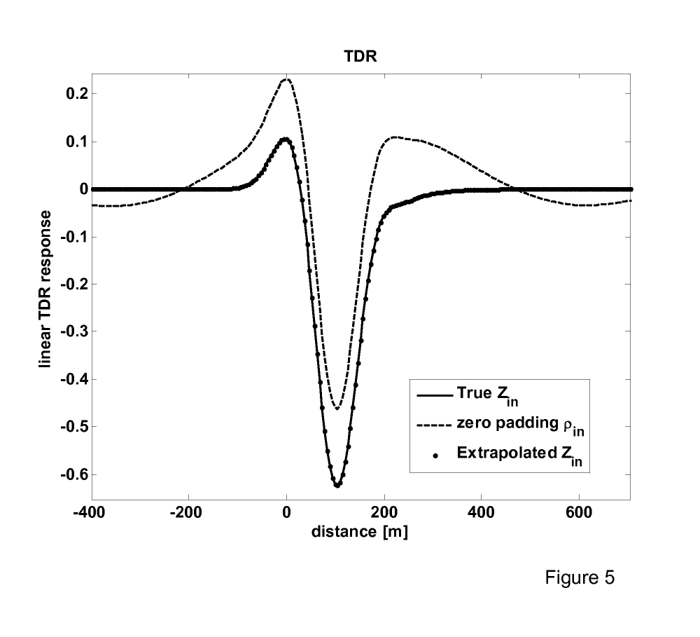

FIG. 5 shows the echo impulse response versus distance. It was achieved by converting the extrapolated input impedance to input reflection (or S₁₁) using a system impedance of Z₀=100Ω, windowing with a low-pass Blackman window (according to FIG. 3) and finally performing a real-valued (Hermitian-symmetry) IFFT with 16 times oversampling. As can be seen, the curve for the extrapolated Zᵢₙ (result of applying an embodiment of the invention) follows the curve for true Zᵢₙ (according to a cable model) very closely. The near-end echo (at about 0 meter) between DSLAM and cable has a positive peak showing that the cable's characteristic impedance is higher than the system impedance. The far-end echo at about 100 meter has a negative peak showing that the termination impedance is lower than the cable's characteristic impedance. Further, the response is close to zero for distances sufficiently separated from the two peaks. For comparison, the zero padding (prior art) curve shows excessive ringing with multiple false peaks both before and after zero distance, which may be confusing for a user.

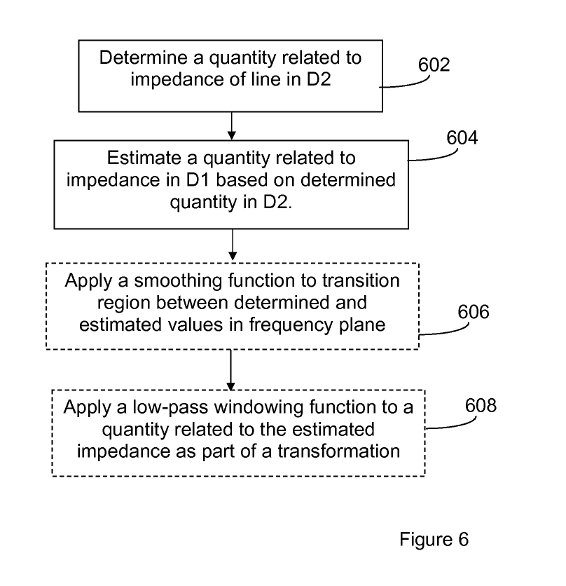

### Exemplifying Procedure, FIG. 6

A generic procedure for estimating a quantity related to impedance (impedance or other parameter related to impedance) in a first frequency interval, D1, of a telecommunication transmission line having a length d according to an exemplifying embodiment will be described below with reference to FIG. 6. The procedure could be executed partly or entirely e.g. in a Transceiver Unit, TU, such as a Digital Subscriber Line Access Multiplexer (DSLAM) (xTU-C) or a Customer Premises Equipment (CPE) (xTU-R), and/or, in a control/management node or tool connected to a TU, e.g. via a network.

A quantity related to impedance of the telecommunication transmission line is determined in an action 602 for at least two frequencies, f1_{D2} and f2_{D2}. The frequencies f1_{D2} and f2_{D2} are comprised in/belong to a second frequency interval D2, and should fulfill the requirement that the line length d times the absolute value of the difference between a line propagation constant (for the first frequency) γ(f1)_{D2} and a line propagation constant (for the second frequency), γ(f2)_{D2}, is less than π, i.e. abs(d*γ(f1)_{D2-d*γ(f2)}_{D2})<π.

Further, a quantity related to impedance in the first frequency interval D1 is estimated in an action 602, based on the determined quantity related to impedance in the second frequency interval D2. The estimating involves the fitting of a Puiseux (e.g. Puiseux, Laurent or Taylor) series to the determined quantity related to impedance in frequency interval D2. The requirement on the frequencies f1_{D2} and f2_{D2} above ensures that the series may be used in the estimation, i.e. that the series is valid for these frequencies. The Puiseux series may contain integer and/or half integer powers of frequency, and may, as previously mentioned, be represented by/simplified to e.g. a Laurent or Taylor series.

In some cases, e.g. when only the fitted series should be used in the estimation (and not also some other series or function derived from the fitted series), a frequency f1_{D1} in frequency interval D1, for which the quantity related to impedance should be estimated should fulfill the requirement:

max(abs(d*γ(f1)_{D2}−d*γ(f1)_{D1}),abs(d*γ(f2)_{D2}−d*γ(f1)_{D1}))<π

That is, the relation between the concerned frequencies in the frequency intervals D1 and D2 should fulfill the above requirement.

The frequency interval D1 may comprise lower and/or higher frequencies than frequency interval D2, and may further overlap frequency. For example, D1 could comprise at least one frequency in which is lower than the lowest frequency in D2

The estimating may further involve, in addition to the fitting of the Puiseux series, determining a function which is valid in D1, by use of the coefficients from the Puiseux series fitted to the determined quantity in frequency interval D2. The function may be e.g. a rational function or another Puiseux series, different from the Puiseux series fitted to the quantity determined in frequency interval D2.

The transmission of which an impedance or other parameter related to impedance is to be estimated, has a first and a second end. The determining of a quantity in the second frequency interval D2 may be based e.g. on an echo measurement performed in the first end of the transmission line, or, on an impedance measurement performed in the first end of the transmission line.

Optionally (thus indicated by a broken line in FIG. 6), a smoothing function may be applied in an action 604. The smoothing function is applied in the frequency plane, to transition region between determined (in interval D2) and estimated (in interval D1) values. The transition region may be a frequency region where the first frequency interval D1 and the second frequency interval D2 overlap. Further, the smoothing function may be a linear combination of determined and estimated values, where the estimated values are given a higher weight in one end of the transition region, and lower weight in the other end of the transition region.

Also optionally, a SELT postprocessing (SELT-P) may be performed on the transmission line in an action 608. The SELT-P involves a transformation of a quantity related to the estimated quantity related to impedance in the first frequency interval D1 between a frequency plane and a time plane. The transformation may then involve the applying of a windowing function e.g. centered approximately around f=0 (c.f. “LP extrapolated” in FIGS. 3 and 4), or, starting approximately at f=0 (c.f. “BP extrapolated” in FIGS. 3 and 4). The applying of windowing functions in said low-frequency regions is enabled by the estimation of frequencies in the low frequency regions. Thus a higher time-domain resolution may be achieved in the transformation.

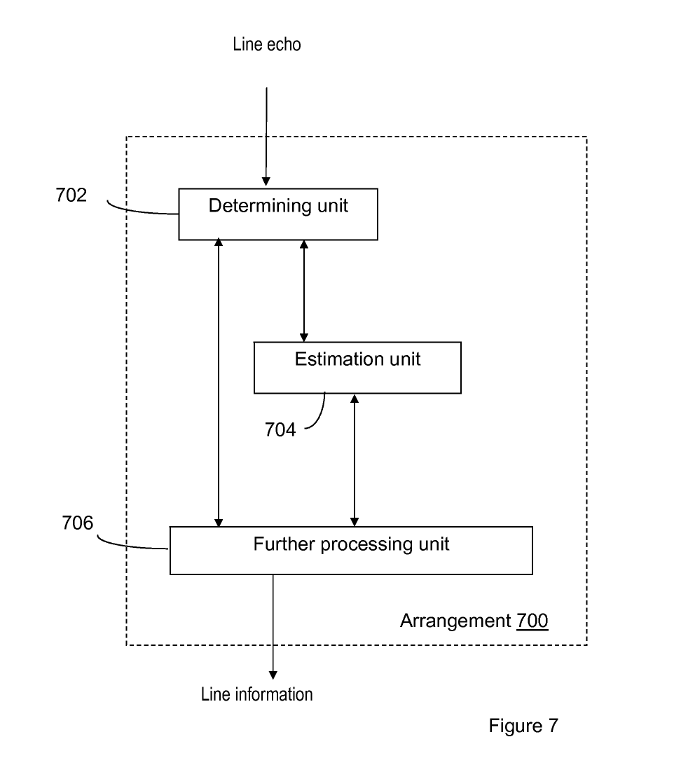

### Exemplifying Arrangement FIG. 7

Below, an exemplifying arrangement in a line communication system, for estimating a quantity related to impedance (impedance or other parameter related to impedance) in a first frequency interval, D1, of a telecommunication transmission line having a length d will be described with reference to FIG. 7. The arrangement may be partly or entirely comprised in a network node, such as e.g. in a Transceiver Unit, TU, such as a Digital Subscriber Line Access Multiplexer (DSLAM) (xTU-C) or a Customer Premises Equipment (CPE) (xTU-R), and/or, in a control/management node or tool connected to a TU, e.g. via a network.

The arrangement 700 comprises processing circuitry configured to perform the actions described above. The processing circuitry may be implemented e.g. by one or more of: a processor or a micro processor and adequate software stored in a memory, a Programmable Logic Device (PLD), Field-Programmable Gate Array (FPGA), Application-Specific Integrated Circuit (ASIC) or other electronic component(s) configured to perform the actions mentioned above.

The arrangement may be implemented to comprise and/or described/regarded as comprising a set of units, which is also illustrated in FIG. 7. The arrangement comprises a determining unit 702, which is adapted to determine quantity related to impedance of the telecommunication transmission line for at least two frequencies, f1_{D2} and f2_{D2}, in a second frequency interval D2, which frequencies fulfills the requirement abs(d*γ(f1)_{D2}−d*γ(f2)_{D2})<π. The arrangement further comprises an estimation unit 704, which is adapted to estimate a quantity related to impedance in the first frequency interval D1 based on the determined quantity related to impedance in the second frequency interval D2, wherein the estimating involves the fitting of a Puiseux series to the determined quantity related to impedance in frequency interval D2.

The arrangement 700 may further comprise a further processing unit 705, adapted to apply a smoothing function to a transition region between frequency interval D1 and D2, and/or performing a SELT post processing (SELT-P) on the transmission line, as previously described.

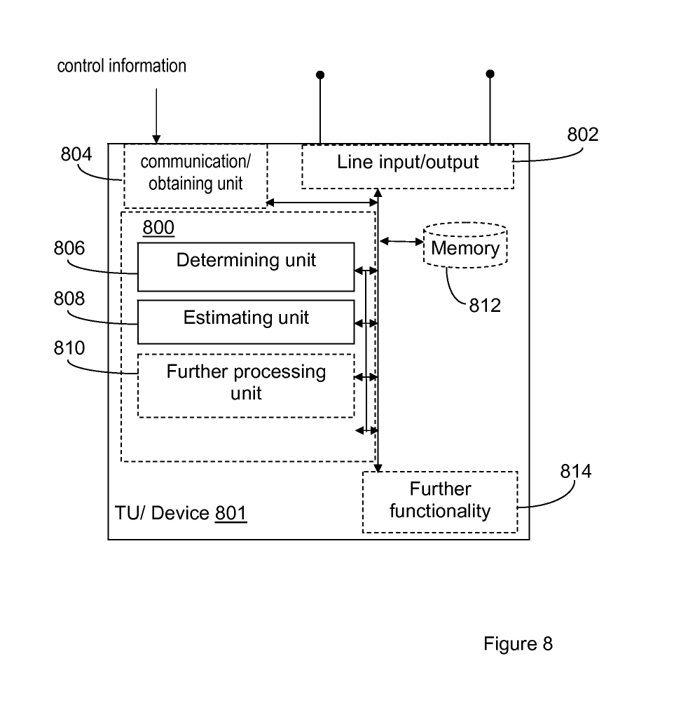

### Exemplifying Arrangements/Nodes, FIGS. 8-10

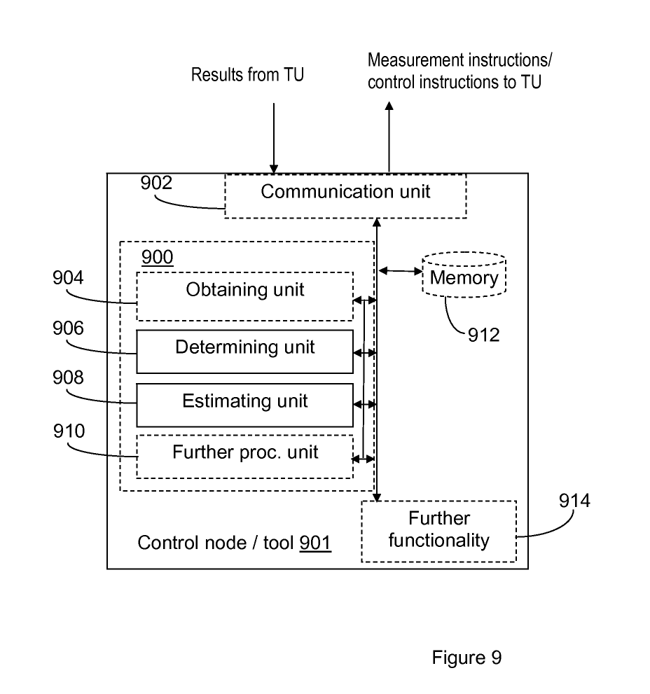

As previously mentioned, the arrangement 700 may be comprised partly or entirely e.g. in a Transceiver Unit, TU, such as a Digital Subscriber Line Access Multiplexer (DSLAM) (xTU-C) or a Customer Premises Equipment (CPE) (xTU-R), or, in a control/management node or tool connected to a TU, e.g. via a network. Cases where the arrangement is comprised in one entity are illustrated in FIGS. 8 and 9. FIG. 8 shows an arrangement 800 comprised in a TU or tool 801. The arrangement may comprise the same processing circuitry and/or units as previously described in conjunction with FIG. 7. The TU or tool 801 may further comprise a line input/output 802, and further functionality 804, 814 for providing regular TU/tool functions. The transmission line for which an estimation is to be performed may be assumed to be connected to the line input/output 802.

FIG. 9 illustrates an arrangement 900 comprised in a control or management node or tool 901. The control node may be e.g. a CPM or APM, or similar. The control node could further be a tool suitable for impedance analysis of transmission lines. When the estimation procedure is to be performed from a control node, measurement on the transmission line could be triggered e.g. by transmission of measurement instructions to TU connected to the transmission line. The result of the measurement may then be received from the TU, e.g. via a communication unit 902. The arrangement 900 has further been illustrated as comprising an obtaining unit 904, adapted to obtain or assist in obtaining information from a device connected to the transmission line.

The arrangements/devices described below may be implemented in different embodiments in analogy with the procedure described above. These will however not all be described here in order to avoid unnecessary repetition.

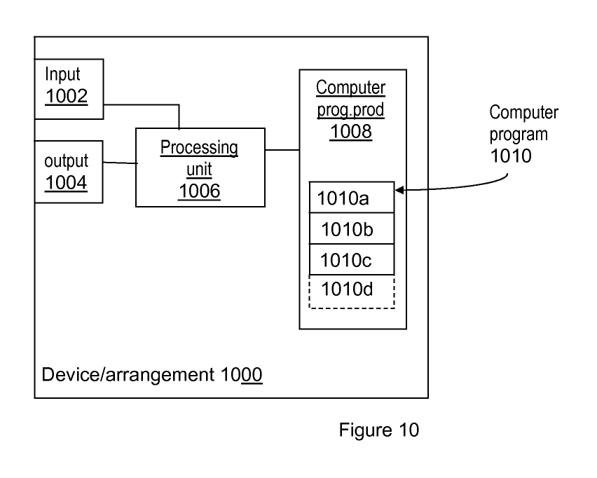

FIG. 10 schematically shows a possible embodiment of an arrangement 1000, which also can be an alternative way of disclosing an embodiment of the arrangement illustrated in any of FIGS. 7-9. Comprised in the arrangement 1000 are here a processing unit 1006, e.g. with a DSP (Digital Signal Processor). The processing unit 1006 may be a single unit or a plurality of units to perform different actions of procedures described herein. The arrangement 1000 may also comprise an input unit 1002 for receiving signals from other entities, and an output unit 1004 for providing signal(s) to other entities. The input unit 1002 and the output unit 1004 may be arranged as an integrated entity.

Furthermore, the arrangement 1000 comprises at least one computer program product 1008 in the form of a non-volatile memory, e.g. an EEPROM (Electrically Erasable Programmable Read-Only Memory), a flash memory and a hard drive. The computer program product 1008 comprises a computer program 1010, which comprises code means, which when executed in the processing unit 1006 in the arrangement 1000 causes the arrangement and/or a node in which the arrangement is comprised to perform the actions e.g. of the procedure described earlier in conjunction with FIG. 6.

The computer program 1010 may be configured as a computer program code structured in computer program modules. Hence, in an exemplifying embodiment, the code means in the computer program 1010 of the arrangement 1000 may comprise an obtaining module 1010a for obtaining e.g. of information on measurements on a transmission line. The arrangement 1000 comprises a determining module 1010b for determining a quantity related to impedance of the telecommunication transmission line for at least two frequencies in a second frequency interval D2. The computer program further comprises an estimation module 1010c for estimating a quantity related to impedance in the first frequency interval D1. The computer program 1010 may further comprise a further processing module 1010d for applying of a smoothing function or performing of SELT post processing as previously described.

The modules 1010a-d could essentially perform the actions of the flow illustrated in FIG. 6, to emulate the arrangement illustrated in any of FIGS. 7-9.

Although the code means in the embodiment disclosed above in conjunction with FIG. 10 are implemented as computer program modules which when executed in the processing unit causes the decoder to perform the actions described above in the conjunction with figures mentioned above, at least one of the code means may in alternative embodiments be implemented at least partly as hardware circuits.

The processor may be a single CPU (Central processing unit), but could also comprise two or more processing units. For example, the processor may include general purpose microprocessors; instruction set processors and/or related chips sets and/or special purpose microprocessors such as ASICs (Application Specific Integrated Circuit). The processor may also comprise board memory for caching purposes. The computer program may be carried by a computer program product connected to the processor. The computer program product may comprise a computer readable medium on which the computer program is stored. For example, the computer program product may be a flash memory, a RAM (Random-access memory) ROM (Read-Only Memory) or an EEPROM, and the computer program modules described above could in alternative embodiments be distributed on different computer program products in the form of memories within the network node.

It is to be understood that the choice of interacting units or modules, as well as the naming of the units are only for exemplifying purpose, and nodes suitable to execute any of the methods described above may be configured in a plurality of alternative ways in order to be able to execute the suggested process actions.

It should also be noted that the units or modules described in this disclosure are to be regarded as logical entities and not with necessity as separate physical entities. Although the description above contains many specificities, these should not be construed as limiting the scope of the invention but as merely providing illustrations of some of the presently preferred embodiments of this invention. It will be appreciated that the scope of the present invention fully encompasses other embodiments which may become obvious to those skilled in the art, and that the scope of the present invention is accordingly not to be limited. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed hereby. Moreover, it is not necessary for a device or method to address each and every problem sought to be solved by the present invention, for it to be encompassed hereby.

### REFERENCES

[U.S. Pat. No. 4,995,006A1] U.S. Pat. No. 4,995,006A1, “Apparatus and method for low-pass equivalent processing”.
[Dodds2006] D. E. Dodds, M. Shafique, B. Celaya, “TDR and FDR Identification of Bad Splices in Telephone Cables”, Proceedings of Canadian Conference on Electrical and Computer Engineering 2006, CCECE'06.

1. Method for estimating a quantity related to impedance in a first frequency interval, D1, of a telecommunication transmission line having a length d, the method comprising:
determining a quantity related to impedance of the telecommunication transmission line for at least two frequencies, f1_{D2} and f2_{D2}, in a second frequency interval D2, for which frequencies the line length d times the absolute value of the difference between a line propagation constant γ(f1)_{D2} and a line propagation constant, γ(f2)_{D2}, is less than π, i.e. abs(d*γ(f1)_{D2}−d*γ(f2)_{D2})<π; and
estimating a quantity related to impedance in the first frequency interval D1 based on the determined quantity related to impedance in the second frequency interval D2;
wherein the estimating involves the fitting of a Puiseux series to the determined quantity related to impedance in frequency interval D2.

2. Method according to claim 1, wherein the Puiseux series contain integer and/or half integer powers of frequency.

3. Method according to claim 1, wherein the Puiseux series is represented by a Laurent or Taylor series with only even powers of the angular frequency in the real part and only odd powers of the angular frequency in the imaginary part.

4. Method according to claim 1, wherein the quantity related to impedance is estimated for a frequency f1_{D1} in frequency interval D1 and where the relation between the concerned frequencies in the frequency intervals D1 and D2 is such that:
max(abs(d*γ(f1)_{D2}−d*γ(f1)_{D1}),abs(d*γ(f2)_{D2}−d*γ(f1)_{D1}))<π

5. Method according to claim 1, wherein at least one frequency in D1 is lower than the lowest frequency in D2.

6. Method according to claim 1, wherein the estimating further involves:
determining a function which is valid in D1, by use of coefficients from the Puiseux series fitted to the quantity determined in frequency interval D2.

7. Method according to claim 6, wherein said function is one of:
a rational function;
a Puiseux series different from the Puiseux series fitted to the quantity determined in frequency interval D2.

8. Method according to claim 1, wherein the transmission line has a first and a second end, and the determining is based on at least one of:
an echo measurement performed in the first end of the transmission line;
an impedance measurement performed in the first end of the transmission line.

9. Method according to claim 1, further comprising:
applying a smoothing function, in the frequency plane, to a transition region between determined and estimated values.

10. Method according to claim 9, wherein the transition region is a frequency region where the first frequency interval D1 and the second frequency interval D2 overlap.

11. Method according to claim 10 wherein the smoothing function is a linear combination of determined and estimated values, where the estimated values are given a higher weight in one end of the transition region, and lower weight in the other end of the transition region.

12. Method according to claim 1, wherein a SELT postprocessing (SELT-P) is performed on the transmission line, which SELT-P involves a transformation of a quantity related to the estimated quantity related to impedance in the first frequency interval D1 between a frequency plane and a time plane, which transformation involves the applying of a windowing function centered approximately around f=0.

13. Method according to claim 1, wherein a SELT postprocessing (SELT-P) is performed on the transmission line, which SELT-P involves a transformation of a quantity related to the estimated quantity related to impedance in the first frequency interval D1 between a frequency plane and a time plane, which transformation involves the applying of a windowing function starting approximately at f=0.

14. Arrangement for estimating a quantity related to impedance in a first frequency interval, D1, of a telecommunication transmission line having a length d, said arrangement comprising processing circuitry configured to:
determine a quantity related to impedance of the telecommunication transmission line for at least two frequencies, f1_{D2} and f2_{D2}, in a second frequency interval D2, for which frequencies the line length d times the absolute value of the difference between a line propagation constant γ(f1)_{D2} and a line propagation constant, γ(f2)_{D2}, is less than π, i.e. abs(d*γ(f1)_{D2}−d*γ(f2)_{D2})<π; and
estimate a quantity related to impedance in the first frequency interval D1 based on the determined quantity related to impedance in the second frequency interval D2, wherein the estimating involves the fitting of a Puiseux series to the determined quantity related to impedance in frequency interval D2.

15. Arrangement according to claim 14, wherein the Puiseux series contain integer and/or half integer powers of frequency.

16. Arrangement according to claim 14, wherein the Puiseux series is represented by a Laurent or Taylor series with only even powers of the angular frequency in the real part and only odd powers of the angular frequency in the imaginary part.

17. Arrangement according to claim 14, wherein the quantity related to impedance is estimated for a frequency f1_{D1} in frequency interval D1 and where the relation between the concerned frequencies in the frequency intervals D1 and D2 is such that:
max(abs(d*γ(f1)_{D2}−d*γ(f1)_{D1}),abs(d*γ(f2)_{D2}−−d*γ(f1)_{D1}))<π

18. Arrangement according to claim 14, wherein at least one frequency in D1 is lower than the lowest frequency in D2.

19. Arrangement according to claim 14, wherein the estimating further involves:
determining a function which is valid in D1, by use of coefficients from the Puiseux series fitted to the quantity determined in frequency interval D2.

20. Method according to claim 19, wherein said function is one of:
a rational function;
a Puiseux series different from the Puiseux series fitted to the quantity determined in frequency interval D2.

21. Arrangement according to claim 14, wherein the transmission line has a first and a second end, and the processing circuitry is further configured to determine the quantity based on one of:
an echo measurement performed in the first end of the transmission line;
an impedance measurement performed in the first end of the transmission line.

22. Arrangement according to claim 14, wherein the processing circuitry is further configured to apply a smoothing function, in the frequency plane, to a transition region between determined and estimated values.

23. Arrangement according to claim 22, wherein the transition region is a frequency region where the first frequency interval D1 and the second frequency interval D2 overlap.

24. Arrangement according to claim 23, wherein the smoothing function is a linear combination of determined and estimated values, where the estimated values are given a higher weight in one end of the transition region, and lower weight in the other end of the transition region.

25. Arrangement according to claim 14, wherein the processing circuitry is further configured to perform SELT postprocessing (SELT-P) on the transmission line, which SELT-P involves a transformation of a quantity related to the estimated quantity related to impedance in the first frequency interval D1 between a frequency plane and a time plane, which transformation involves the applying of a windowing function centered approximately around f=0.

26. Arrangement according to claim 14, wherein the processing circuitry is further configured to perform SELT postprocessing (SELT-P) on the transmission line, which SELT-P involves a transformation of a quantity related to the estimated quantity related to impedance in the first frequency interval D1 between a frequency plane and a time plane, which transformation involves the applying of a windowing function starting approximately at f=0.

27. Device comprising an arrangement according to claim 14.

28. Network node comprising an arrangement according to claim 14.

29. Computer program, comprising computer readable code means, which when run in an arrangement or device according to claim 14 causes the device to perform the corresponding method according to claim 1.

30. Computer program product, comprising the computer program according to claim 29.
